(19) United States
(12) Patent Application Publication
(10) Pub. No.: US 2020/0026903 A1
(43) Pub. Date: Jan. 23, 2020

(54) LIGHT COLLIMATOR, MANUFACTURING METHOD THEREOF AND OPTICAL FINGERPRINT IDENTIFICATION DEVICE

(71) Applicant: BOE TECHNOLOGY GROUP CO., LTD., Beijing (CN)

(72) Inventors: Xiaoquan HAI, Beijing (CN); Haisheng WANG, Beijing (CN); Lei WANG, Beijing (CN)

(21) Appl. No.: 16/409,558

(22) Filed: May 10, 2019

(30) Foreign Application Priority Data
Jul. 19, 2018 (CN) 201810799327.8

(51) Int. Cl. G06K 9/00; G02B 5/20; H01L 33/50; G02B 27/30

(52) U.S. Cl. CPC G06K 9/00087; G02B 5/20; G06K 2009/0006; G02B 27/30; H01L 33/50

(57) ABSTRACT

The present disclosure relates to a light collimator, a manufacturing method thereof, and an optical fingerprint identification device. The light collimator includes a first filter film area and a plurality of second filter film units distributed in the first filter film area to form a flat film with the first filter film area. The light that the first filter film area allows to pass has a wavelength different from a wavelength of the light that the plurality of second filter film units allows to pass. With the solution of the present disclosure, the present disclosure can overcome existing difficulties in optical collimation structures.

### CROSS REFERENCE TO RELATED APPLICATION

This application is based upon, claims the benefit of, and priority to Chinese Patent Application No. 201810799327.8, filed on Jul. 19, 2018, where the entire contents thereof are incorporated herein by reference.

### TECHNICAL FIELD

The present disclosure relates to the field of display technologies and, more particularly, to a light collimator, a manufacturing method thereof, and an optical fingerprint identification device.

### BACKGROUND

In the process of optical fingerprint identification, when a distance between a finger and a sensor is large, scattering of the light reflected by the finger may cause the acquired image to be blurred, and the fingerprint information identified through the light received by the sensor may be inaccurate. The sensing method of existing fingerprint identification includes a through-hole filtering method as shown in FIG. 12, or a lens-plus-aperture method. As shown in FIG. 12, by providing a through hole 102 in material above the sensor 101, a light receiving angle of the light incident on the sensor 101 is sufficiently small to distinguish the valley from the ridge information of the fingerprint. To achieve the structure of an ideal through hole as shown on the left side of FIG. 12, the sensor 101 has to be made of a particular material which can have a high aspect ratio (the depth to width ratio). However, in the existing lithography process, ‘chamfering’-like structure may occur, which may increase the light-receiving angle (see the angles α′ [symbol] α″ on the right side of FIG. 12) and cause crosstalk of adjacent valley and ridge information. The identified fingerprint information is thus inaccurate, and consequently, the image is blurred. Also, the lens-plus-aperture is hard to manufacture.

It should be noted that the information disclosed in the Background section above is only for enhancement of understanding of the background of the present disclosure, and thus may include information that does not constitute prior art known to those of ordinary skill in the art.

### SUMMARY

It is an objective of the present disclosure to provide a light collimator, a manufacturing method thereof, and an optical fingerprint identification device, which can overcome the problem that the existing optical collimation structure is difficult to manufacture.

According to an aspect of the present disclosure, a light collimator is provided, including:

a first filter unit comprising a plurality of through holes; and

a plurality of second filter units disposed within the through holes, wherein light that the first filter unit allows to pass has a wavelength different from a wavelength of the light that the plurality of second filter units allows to pass.

According to another aspect of the present disclosure, an optical fingerprint identification device is provided, including:

a light emitting device configured to emit light in fingerprint identification, and the emitted light is reflected by a fingerprint;

the light collimator according to any one of claims 1 to 8, disposed under the light emitting device and configured to receive the light reflected by the fingerprint; and

a sensor disposed under the light collimator and configured to receive the light transmitted through the light collimator.

According to another aspect of the present disclosure, a method for manufacturing a light collimator is provided, the method including:

in step S21, forming a first filter unit material on a substrate;

in step S22, patterning the first filter unit material with a mask having a plurality of holes to form a pattern of the first filter unit; and

in step S23, forming a second filter unit material with the mask having a plurality of holes, so that the second filter unit material is deposited through the holes to a region where the first filter unit material is not formed to obtain a plurality of second filter units, wherein light that the first filter unit allows to pass has a wavelength different from a wavelength of the light that the plurality of second filter units allows to pass.

In the technical solutions provided by the embodiments of the present disclosure, a plurality of second filter units are provided in the through holes in the first filter unit. The light that the first filter unit allows to pass has a wavelength different from a wavelength of the light that the plurality of second filter units allows to pass. In this regard, the second filter units allow passage of light of a particular wavelength, and the sizes of the second filter units can be designed to be small, and thus the present disclosure can achieve the function of light collimation. In addition, the second filter units can be formed through a mask without requiring a particular process, which can reduce the process difficulty.

### BRIEF DESCRIPTION OF THE DRAWINGS

The above and other features and advantages of the present disclosure will become more apparent from the detailed description of exemplary embodiments. Understandably, the drawings in the following description are only some of the embodiments of the present disclosure, and other drawings may be obtained from these drawings by those skilled in the art without any creative effort.

FIG. 1 illustrates a plan view of a light collimator according to an exemplary embodiment of the present disclosure.

FIG. 2 is a cross-sectional view taken along line II-IF in FIG. 1.

FIG. 3 shows a schematic structural diagram of an optical fingerprint identification device according to an exemplary embodiment of the present disclosure.

FIG. 4 is a diagram showing an identification effect of an optical fingerprint identification device according to an embodiment of the present disclosure.

FIG. 5 is a diagram showing another identification effect of an optical fingerprint identification device according to an embodiment of the present disclosure.

FIG. 6 illustrates a flow chart of a method for manufacturing a light collimator according to an exemplary embodiment of the present disclosure.

FIGS. 7 to 11 illustrate steps of a process for manufacturing a light collimator.

FIG. 12 shows a through-hole filtering method in the related arts.

### DETAILED DESCRIPTION

Exemplary embodiments will now be described more fully with reference to the accompanying drawings. However, the exemplary embodiments can be embodied in a variety of forms and should not be construed as being limited to the embodiments set forth herein. Rather, these embodiments are provided to make this disclosure to be thorough and complete, and to fully convey the concept of the exemplary embodiments to those skilled in the art. The described features, structures, or characteristics may be combined in any suitable manner in one or more embodiments. In the following description, numerous specific details are set forth to provide a thorough understanding of the embodiments of the present disclosure. However, one skilled in the art will appreciate that the technical solution of the present disclosure may be practiced without one or more of the specific details, or other methods, components, materials, devices, steps, etc. may be employed. In other instances, well-known technical solutions are not shown or described in detail to avoid obscuring aspects of the present disclosure.

In addition, the drawings are merely schematic illustrations of the present disclosure, and are not necessarily drawn to scale. The same reference numerals in the drawings denote the same or similar parts, and the repeated description thereof will be omitted.

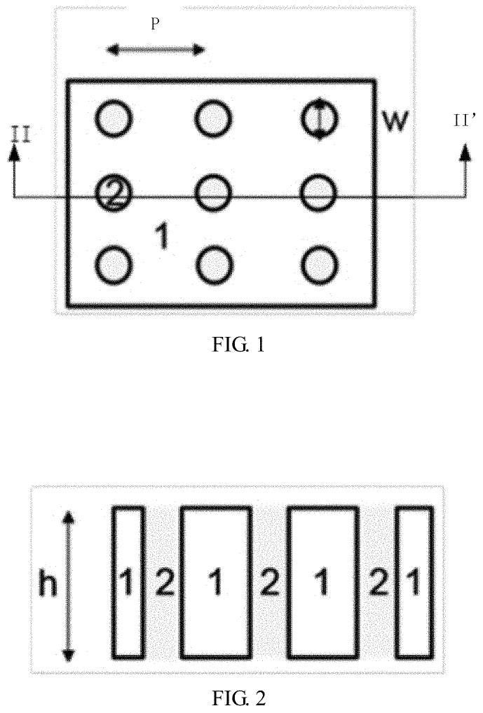

FIG. 1 illustrates a plan view of a light collimator according to an exemplary embodiment of the present disclosure, and FIG. 2 is a cross-sectional view taken along line in FIG. 1. As shown in FIGS. 1 and 2, the light collimator includes a first filter unit 1 and a plurality of second filter units 2. The first filter unit 1 includes a plurality of through holes. The plurality of second filter units 2 are disposed within the through holes.

According to an embodiment, the plurality of second filter units 2 may be distributed in the first filter unit 1 to form a flat film with the first filter unit 1. The light that the first filter unit 1 allows to pass has a wavelength different from a wavelength of the light that the plurality of second filter units 2 allows to pass.

According to an embodiment, the light that the plurality of second filter units allows to pass is absorbed by the first filter unit.

According to an embodiment, light collimated by the collimator is transmitted via the plurality of second filter units.

In the light collimator shown in FIG. 1, the plurality of second filter units 2 may have various shapes such as circles, squares or hexagons, etc., and in FIG. 1, the plurality of second filter units 2 are circle-shaped, for example. The plurality of second filter units 2 may be distributed in the first filter unit 1 in an array. Specifically, as shown in FIG. 1, the plurality of filter units 2 arranged in the first filter unit 1 are formed in an array of three rows and three columns in the plan view.

The diameter or side length of each second filter unit 2 is w, and the thickness of the flat film (i.e., the light collimator) is H, wherein the thickness of the light collimator refers to a thickness along a depth direction of the through holes, w and H satisfy the following relationship:

θ=w/2H,

where θ is a half light receiving angle of the flat film (i.e., the light collimator), the light receiving angle α=2θ represents the angle at which the light reflected by the minimum identifiable valley and ridge of the fingerprint is incident on the flat film, and θ is less than or equal to 5.7°.

The thickness H of the flat film is 42 to 100 μm, and the diameter or side length w of each of the second filter units 2 is 6 μm or less, and the pitch P between the plurality of second filter units 2 (see FIG. 1) may be determined according to the light transmittance of the light collimator, that is, depending on the responsiveness of the sensor in the optical fingerprint identification device. For example, in order to achieve a desired light transmittance, the pitch P between the plurality of second filter units 2 in the light collimator can be adjusted. For example, the smaller the pitch is, the greater the light transmittance will be, the larger the pitch, and the smaller the light transmittance.

The first filter unit 1 may be formed by alternately laminating dielectric layers of different refractive indices. Each of the second filter units may be formed by alternately laminating dielectric layers of different refractive indices. For example, the number of dielectric layers alternately laminated in the first filter unit is different from the number of dielectric layers alternately laminated in the second filter unit. The thickness of each of the dielectric layers alternately laminated in the first filter unit is different from the thickness of each of the dielectric layers alternately laminated in second filter unit. That is, both the first filter unit 1 and the second filter unit 2 may be formed by lamination of film layers, but the number and thickness of the film layers may be different.

In the technical solutions provided by the embodiments of the present disclosure, a plurality of second filter units are distributed in the first filter unit to form a flat film with the first filter film area. The light that the first filter unit allows to pass has a wavelength different from a wavelength of the light that the plurality of second filter units allows to pass. In this regard, the second filter units allow passage of light of a particular wavelength, and the sizes of the second filter units can be designed to be small. For example, by designing the diameter or side length of the second filter unit and the thickness of the light collimator, the present disclosure can achieve the function of light collimation. In addition, the second filter unit can be formed through a mask without requiring a particular process to form a high aspect ratio through hole or an aperture as in the prior art, which can reduce the process difficulty.

In addition, in the technical solutions provided by the disclosed embodiments, the first filter unit and the plurality of second filter units are formed by laminating film layers of different refractive indexes, and the main structure generally relates to the film layers without including other optical devices. Therefore, the overall thickness can be made relatively small.

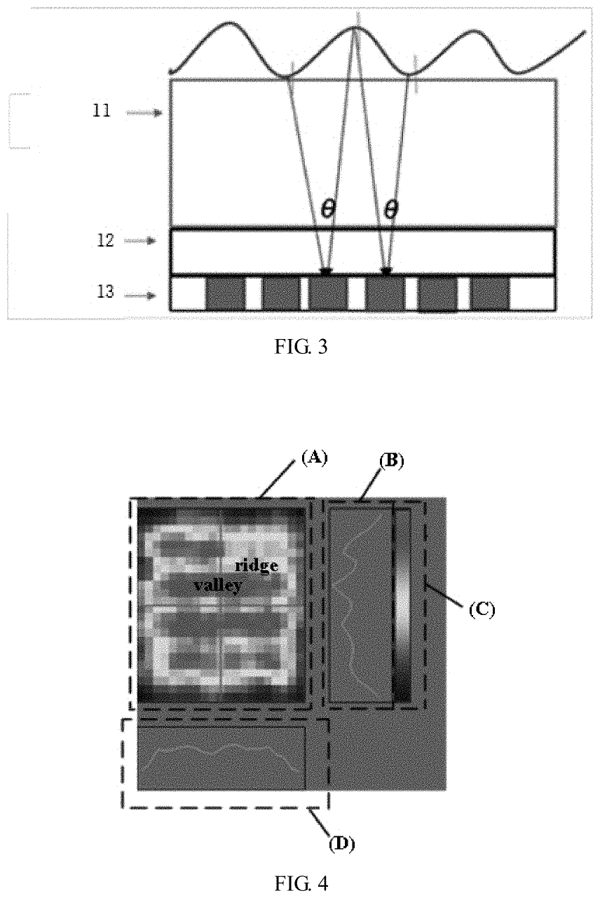

FIG. 3 shows a schematic structural diagram of an optical fingerprint identification device according to an exemplary embodiment of the present disclosure. The optical fingerprint identification device includes a light emitting device 11, a light collimator 12, and a sensor 13. The light emitting device 11 is configured to emit light when performing fingerprint identification, and the emitted light is reflected by the fingerprint. The light collimator 12 is disposed below the light emitting device 11 and configured to receive the light reflected by the fingerprint. The sensor 13 is disposed below the light collimator 12, and configured to receive light transmitted through the light collimator 12.

The light collimator 12 may have a structure as shown in FIGS. 1 and 2. The principle of the optical fingerprint identification device will be described below with reference to FIGS. 1-3.

The light emitting device 11 may be various light emitting devices, such as an OLED (Organic Light Emitting Diode), which may include a cover glass, an optically clear adhesive (OCA), a polarizer, a thin film package TFE, a cathode, an EL light emitting layer, film layers and a substrate back plate or the like (not shown).

The sensor 13 may be a sensor array formed by a plurality of sensor units, such as a photosensitive sensor array.

The light collimator 12 is located on the lower surface layer of the light emitting device 11 and has the property of screening lights. In the fingerprint identification process, when the finger touches the display screen, the second filter units 2 in the light collimator 12 can allow passage of light of a particular wavelength, and can select lights with a small angle and approximately collimated, and allow them to reach the sensor 13 below. The sensor 13 can detect the intensity of the received light. Since the energies of the diffused lights reflected from the valley and the ridge are different, the light intensities detected by the sensor 13 are different, thereby acquiring fingerprint information.

Optionally, the first filter unit 1 may include a long-pass filter film to allow light of a near infrared wavelength range (for example, 780 nm to 3000 nm) to pass. The plurality of second filter units 2 each may include a short-pass filter film to allow light of a visible wavelength range (e.g., 380 nm to 780 nm) to pass. For example, the first filter unit 1 allows only light of a long wavelength (λ0) to be transmitted, and light of a wavelength smaller than λ0 is filtered and absorbed. The plurality of second filter units 2 allow only light of a short wavelength (λ1) to be transmitted, and light of a wavelength longer than λ1 is filtered and absorbed.

The first filter unit 1 and the plurality of second filter units 2 may be formed by alternately laminating a plurality of dielectric layers with high and low refractive indices, and the center wavelength can be precisely controlled to a desired range after a specific film system design. When the finger touches the display screen, the light reflected by the finger is filtered and absorbed by the first filter unit 1, and can pass through the plurality of second filter units 2 to reach the sensor 13 below.

For example, the plurality of second filter units 2 are circular shapes, the radius of each second filter unit 2 is w, a pitch between the plurality of second filter units 2 is P, and the thickness of the light collimator is H. Referring to FIG. 3, w and H satisfy the following relationship:

θ=w/2H,

where θ is a half light receiving angle of the flat film, and the light receiving angle α=2θ represents the angle at which the light reflected by the minimum identifiable valley and ridge of the fingerprint is incident on the flat film. The half light receiving angle θ for example is θ=5.7°. In order to achieve a more precise distinguishing of valley and ridge, the half light receiving angle can take an angle smaller than 5.7°. According to an embodiment, w may be 6 μm, and H may be 42 μm in order to meet the requirement of the light receiving angle. The plurality of second filter units 2 are formed by alternately laminating a plurality of dielectric layers of high and low refractive indices. The center wavelength can be precisely controlled to the visible light range (380 nm to 780 nm) and the film thickness can be controlled to 42 μm after a specific film system design. The first filter unit is formed by alternately laminating a plurality of dielectric layers of high and low refractive indices. The center wavelength can be precisely controlled in the near-infrared range (800 nm to 1200 nm), and the film thickness can be controlled to 42 μm after a specific film system design. When the finger touches the display screen, the light emitted by the OLED (visible range) is reflected back by the finger, but is filtered and absorbed by the first filter film area 1, and can transmit through the plurality of second filter units 2 to reach the sensor 3 below the light collimator 12. The sensor 13 can detect the intensity of the received light, and the energies of the diffused lights reflected from the valley and the ridge are different, and the light intensities detected by the sensor 13 are different, thereby acquiring fingerprint information and distinguishing the information of the valley from the information of the ridge.

An optical simulation is performed with the parameters w, P, the first filter unit 1 and the plurality of second filter units 2 of the above design, and the results of the optical simulation shown in FIG. 4 are obtained.

The figure (A) in FIG. 4 shows a plane view of a three-dimensional intensity distribution of light obtained by the optical simulation, the figure (B) in FIG. 4 shows a left view of the three-dimensional density distribution, the figure (B) in FIG. 4 shows a front view of the three-dimensional density distribution, and the figure (C) in FIG. 4 shows that light intensity changes from high to low, as seen from top to bottom in FIG. 4.

The peaks and valleys in (B) correspond to the ridges and valleys in (A). As can be seen from the figures, the intensity corresponding to the valley of fingering is the maximum, the intensity corresponding to the ridge of fingering is lower than the intensity corresponding to the valley of fingering. By using the structure in the embodiment, the ridge and valley of a fingerprint can be clearly distinguished, without crosstalk of other stray lights, which can achieve precise identification.

By adopting the technical solution provided by the embodiments of the present disclosure, the entire film optical layer structure has a thickness of less than 50 μm as a whole, and is lighter and thinner than that of the existing structure.

According to an alternative embodiment, the first filter unit 1 may include a cut-off filter film to allow passage of light in a non-visible wavelength range, and the plurality of second filter units 2 may include a band-pass filter film to allow light in the visible wavelength range to pass. Specifically, the light for fingerprint identification belongs to the visible light range, and the first filter unit 1 can be precisely controlled to have a center wavelength in a desired range (the non-visible light range) after a specific film system design, and the plurality of second filter units can be precisely controlled to have a center wavelength in a desired range (the visible light range). When the finger touches the display screen, the light emitted by the OLED (the visible light range) is reflected back by the finger, is filtered and absorbed by the first filter unit 1 (i.e., the cut-off filter film) in the film optical layer, and can pass through the plurality of second filter units 2 (i.e., band pass filters) to reach the sensor 13 below the light collimator 12. The sensor 13 can detect the intensity of the received light, and the energies of the diffused lights reflected from the valley and the ridge are different, and the light intensities detected by the sensor 13 are different, thereby acquiring fingerprint information.

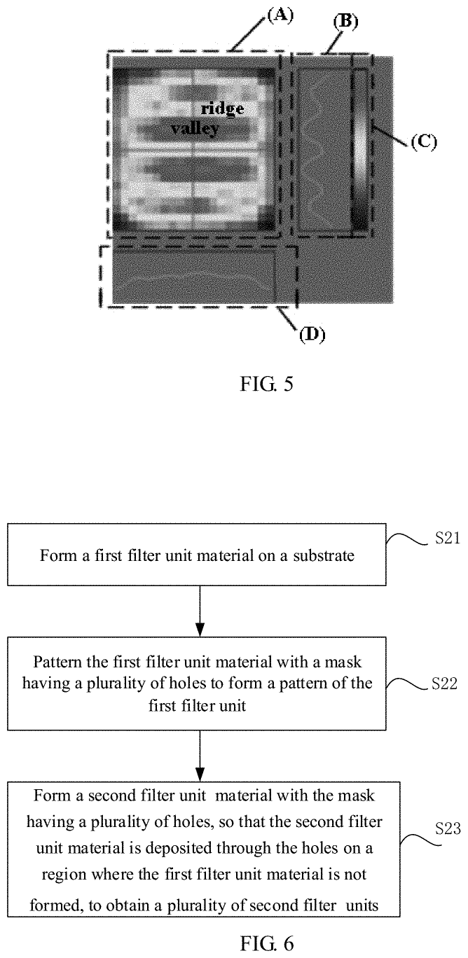

An optical simulation is performed with the parameters w (6 μm), P, the first filter film area 1 (the cut-off filter film), and the plurality of second filter units 2 (the band-pass filter film system) of the above design, and the optical simulation results are shown in FIG. 5.

The figure (A) in FIG. 5 shows a plane view of a three-dimensional intensity distribution of light obtained by the optical simulation, the figure (B) in FIG. 5 shows a left view of the three-dimensional density distribution, the figure (B) in FIG. 5 shows a front view of the three-dimensional density distribution, and the figure (C) in FIG. 5 shows that light intensity changes from high to low, as seen from top to bottom in FIG. 5.

The peaks and valleys in (B) correspond to the ridges and valleys in (A). As can be seen from the figures, the intensity corresponding to the valley of fingering is the maximum, the intensity corresponding to the ridge of fingering is lower than the intensity corresponding to the valley of fingering. By using the structure in the embodiment, the ridge and valley of a fingerprint can be clearly distinguished, without crosstalk of other stray lights, which can achieve precise identification.

According to an exemplary embodiment, in order to achieve a desired light transmittance, the pitch between the plurality of second filter units 2 in the light collimator may be adjusted. For example, the smaller the pitch is, the greater the light transmittance is; and the larger the pitch is, the smaller the light transmittance is.

Additionally, according to an exemplary embodiment, the thickness of the light collimator may be adjusted to achieve a desired light receiving angle. The smaller the thickness, the larger the light receiving angle; and the larger the thickness, the smaller the light receiving angle.

FIG. 6 illustrates a flow chart of a method of manufacturing a light collimator according to an exemplary embodiment of the present disclosure. The method includes the following steps.

In S21, a first filter unit material is formed on a substrate.

In S22, the first filter unit material is patterned with a mask having a plurality of holes to form a pattern of the first filter unit.

In S23, a second filter unit material is formed with the mask having a plurality of holes, so that the second filter unit material is deposited through the holes on a region where the first filter unit material is not formed, so as to obtain a plurality of second filter units. The light that the first filter unit allows to pass has a wavelength different from a wavelength of the light that the plurality of second filter units allows to pass.

The method may further include repeating the steps S21 to S23 to form a first filter unit alternately laminated with dielectric layers of different refractive indices and a second filter unit alternately laminated with dielectric layers of different refractive indices. In each repetition, the refractive index of the first unit material used in step S21 is different from the refractive index of the first filter unit material used in step S21 in the previous repetition; and the refractive index of the second filter material used in step S23 is different from the refractive index of the second filter material used in the previous step 3 in the previous repetition. Through this lamination method, the first filter unit can be obtained by laminating a plurality of dielectric materials having different refractive indices, and the second filter unit can be obtained by laminating a plurality of dielectric materials having different refractive indices.

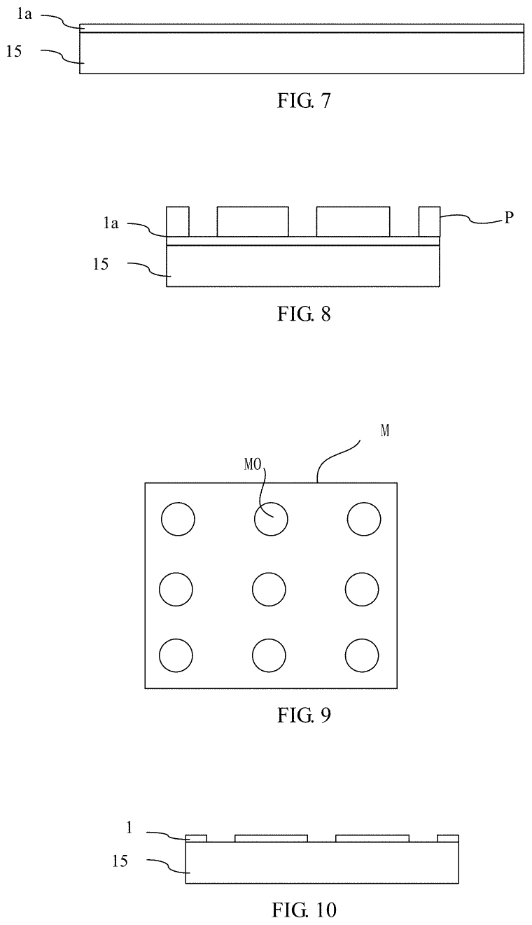

FIGS. 7 to 11 illustrate a specific manufacturing process.

First, a first filter unit material 1a is formed (for example, deposited) on a substrate 15, as shown in FIG. 7.

Next, a photoresist P is formed with a mask M having a plurality of holes, as shown in FIG. 8. A plan view of the mask M is as shown in FIG. 9, and the mask includes a plurality of holes (for example, circular holes) M0. The positions of the holes M0 correspond to the plurality of second filter units 2.

Thereafter, the region not covered by the photoresist P is etched, and then the photoresist is removed to obtain a pattern of the first filter unit 1, as shown in FIG. 10.

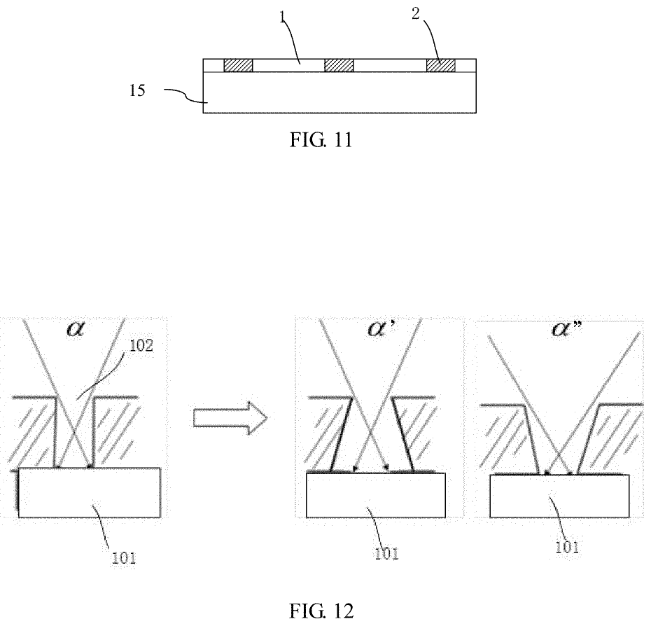

Next, a second filter material 2a is formed (for example, deposited) on the structure as shown in FIG. 10 with the mask shown in FIG. 9, and the second filter material 2a can be deposited on the area of the filter film that is etched away through the holes in the mask, as shown in FIG. 11.

The steps described above with reference to FIGS. 7 to 11 may be repeated to further form the first filter unit 1 and the second filter units 2 which are formed by alternately laminating dielectric layers having different refractive indices.

After the structure shown in FIG. 11 is manufactured, a peeling process may be performed to peel the substrate. Alternatively, the lower surface of the light emitting device may be used as a substrate, or the package of the sensor may be used as a substrate, so that the lift-off process may be omitted.

The manufacturing of the light collimator provided by the present application can be achieved by the above process steps.

Other embodiments of the disclosure will be apparent to those skilled in the art from consideration of the specification and practice of the disclosure disclosed here. This application is intended to cover any variations, uses, or adaptations of the disclosure following the general principles thereof and including such departures from the present disclosure as come within known or customary practice in the art. It is intended that the specification and examples be considered as exemplary only, with a true scope and spirit of the disclosure being indicated by the following claims.

1. A light collimator, comprising:
a first filter unit comprising a plurality of through holes; and
a plurality of second filter units disposed within the through holes, wherein light that the first filter unit allows to pass has a wavelength different from a wavelength of the light that the plurality of second filter units allows to pass.

2. The light collimator according to claim 1, wherein the light that the plurality of second filter units allows to pass is absorbed by the first filter unit.

3. The light collimator according to claim 2, wherein light collimated by the collimator is transmitted via the plurality of second filter units.

4. The light collimator according to claim 1, wherein:
the plurality of second filter units each is in a shape of one of a circle, a square, or a hexagon;
a diameter or a side length of each of the second filter units is w; and
a thickness of the light collimator is H, wherein the thickness of the light collimator refers to a thickness along a depth direction of the through holes, w and H satisfy a relationship:
θ=w/2H
where θ is a half receiving angle of the light collimator and θ is less than or equal to 5.7°.

5. The light collimator according to claim 1, wherein the light collimator has a thickness H of 42 to 100 μm, and a diameter or a side length of each of the second filter units w is 6 μm or less.

6. The light collimator according to claim 1, wherein the first filter unit is formed by alternately laminating a plurality of dielectric layers having different refractive indices; and each of the second filter units is formed by alternately laminating a plurality of dielectric layers having different refractive indices.

7. The light collimator according to claim 5, wherein:
the number of dielectric layers alternately laminated in the first filter unit is different from the number of dielectric layers alternately laminated in each of the second filter units; and
a thickness of each of the plurality of dielectric layers laminated in the first filter unit is different from a thickness of each of the plurality of dielectric layers laminated in each of the second filter units.

8. The light collimator according to claim 1, wherein the first filter unit comprises a long-pass filter film which allows light of a first wavelength range to pass, the plurality of second filter units each comprises a short-pass filter film which allows light of a second wavelength range to pass, wherein the first wavelength range is from 800 nm to 1200 nm and the second wavelength range is from 380 nm to 780 nm.

9. The light collimator of claim 1, wherein the first filter unit comprises a cut-off filter film which allows light of a third wavelength range to pass, the plurality of second filter units each comprises a band-pass filter film which allows light of a second wavelength range to pass, wherein the second wavelength range is from 380 nm to 780 nm, and the third wavelength range is other wavelength range than the second wavelength range.

10. An optical fingerprint identification device, comprising:
a light emitting device configured to emit light when fingerprint identification is performed, wherein the emitted light is reflected by a fingerprint;
a light collimator disposed under the light emitting device and configured to receive the light reflected by the fingerprint; and
a sensor disposed under the light collimator and configured to receive the light transmitted through the light collimator, wherein the light collimator comprises:
a first filter unit comprising a plurality of through holes; and
a plurality of second filter units disposed within the through holes, wherein light that the first filter unit allows to pass has a wavelength different from a wavelength of the light that the plurality of second filter units allows to pass.

11. The device according to claim 10, wherein the light that the plurality of second filter units allows to pass is absorbed by the first filter unit.

12. The device according to claim 11, wherein light collimated by the collimator is transmitted via the plurality of second filter units.

13. The device according to claim 10, wherein:
the plurality of second filter units each is in a shape of one of a circle, a square, or a hexagon;
a diameter or a side length of each of the second filter units is w; and
a thickness of the light collimator is H, wherein the thickness of the light collimator refers to a thickness along a depth direction of the through holes, w and H satisfy a relationship:
θ=w/2H
where θ is a half receiving angle of the light collimator and θ is less than or equal to 5.7°.

14. The device according to claim 10, wherein the light collimator has a thickness H of 42 to 100 μm, and a diameter or a side length of each of the second filter units w is 6 μm or less.

15. The device according to claim 10, wherein the first filter unit is formed by alternately laminating a plurality of dielectric layers having different refractive indices; and each of the second filter units is formed by alternately laminating a plurality of dielectric layers having different refractive indices.

16. The device according to claim 15, wherein:
the number of dielectric layers alternately laminated in the first filter unit is different from the number of dielectric layers alternately laminated in each of the second filter units; and
a thickness of each of the plurality of dielectric layers laminated in the first filter unit is different from a thickness of each of the plurality of dielectric layers laminated in each of the second filter units.

17. The device according to claim 10, wherein the first filter unit comprises a long-pass filter film which allows light of a first wavelength range to pass, the plurality of second filter units each comprises a short-pass filter film which allows light of a second wavelength range to pass, wherein the first wavelength range is from 800 nm to 1200 nm and the second wavelength range is from 380 nm to 780 nm.

18. The device according to claim 10, wherein the first filter unit comprises a cut-off filter film which allows light of a third wavelength range to pass, the plurality of second filter units each comprises a band-pass filter film which allows light of a second wavelength range to pass, wherein the second wavelength range is from 380 nm to 780 nm, and the third wavelength range is other wavelength range than the second wavelength range.

19. A method for manufacturing a light collimator, comprising:
(i) forming a first filter unit material on a substrate;
(ii) patterning the first filter unit material with a mask having a plurality of holes to form a pattern of the first filter unit; and
(iii) forming a second filter unit material with the mask having a plurality of holes, such that the second filter unit material is deposited through the holes to a region where the first filter unit material is not formed to obtain a plurality of second filter units, wherein light that the first filter unit allows to pass has a wavelength different from a wavelength of the light that the plurality of second filter units allows to pass.

20. The method according to claim 19, further comprising:
repeating steps(i), (ii), and (iii) to form a first filter unit by alternately laminating dielectric layers of different refractive indices and a second filter unit formed by alternately laminating dielectric layers of different refractive indices;
wherein, in each repetition, the refractive index of the first filter unit material used in step (i) is different from the refractive index of the first filter unit material used in step (i) in a previous repetition, and the refractive index of the second filter unit material used in step (iii) is different from the refractive index of the second filter unit material used in a previous repetition of step (iii).
